(19) United States
(12) Patent Application Publication
(10) Pub. No.: US 2007/0085173 A1
(43) Pub. Date: Apr. 19, 2007

(54) Method and apparatus for providing double-sided cooling of leadframe-based wire-bonded electronic packages

(75) Inventor: Xuejun Fan, Chandler, AZ (US)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/576,615

(22) PCT Filed: Oct. 14, 2004
(86) PCT No.: PCT/IB04/52097

§ 371 Date: Apr. 17, 2006

Related U.S. Application Data
(60) Provisional application No. 60/512,561, filed on Oct. 17, 2003.

(51) Int. Cl. H01L 21/00

(52) U.S. Cl. 257/666; 438/123

(57) ABSTRACT

A method and apparatus for providing double-sided cooling of leadframe-based wire-bonded electronic packages. The method includes the steps of: positioning a plurality of heatslug members (140) over a corresponding plurality of electronic packages (100′) formed on a leadframe strip (142), wherein each of the heatslug members includes a heatslug (130) and a plurality of legs (144) for supporting the heatslug over a respective one of the electronic packages; introducing a molding compound (132) between each heatslug member and its respective electronic package; curing the molding compound; and cutting the heatslug members and separating the electronic packages (100) from the leadframe strip, such that each electronic package includes a heatslug for cooling a first side of the electronic package.

The present invention relates in general to integrated circuit chip packaging, and more particularly, to a method and apparatus for providing double-sided cooling of leadframe-based wire-bonded electronic packages.

As the speed and component density of modern integrated circuit chips continues to increase, the heat generated by the chips also generally increases. Techniques for better dissipating the heat from integrated circuit chips are thus desirable, especially with higher performance/power devices.

Existing integrated circuit chip packages, such as power MOSFET packages, introduce significant thermal resistance, due to their inability to transfer heat away from the integrated circuit chip. Unfortunately, this limits the power dissipation and performance of the integrated circuit chip. One technique for improving heat dissipation in a leadframe-based wire-bonded integrated circuit chip package involves exposing the leadframe on the bottom of the package through large, integrated metal pads. By soldering this improved integrated circuit chip package to a printed circuit board, a very low impedance heat path is created via the metal pads, enabling larger output currents from, and cooler operation of, the integrated circuit chip. However, it would still be desirable to further increase the heat dissipation and performance of this type of integrated circuit chip package by integrating a heatslug on the top of the package to provide double-sided cooling. The placement of a heatslug on the top of the package, however, increases the complexity of package assembly (and its cost) because the heatslug must be insulated from the leadframe in some manner (e.g., by treating the surface of the leadframe).

There is a need, therefore, for a method and apparatus for providing double-sided cooling of leadframe-based wire-bonded electronic packages. There is also a need for a method and apparatus for integrating a heatslug on the top of leadframe-based wire-bonded electronic package, wherein the heatslug is insulated from the leadframe, and wherein the package can be assembled/produced in a simple, cost-effective manner.

The present invention provides a method and apparatus for providing double-sided cooling of leadframe-based wire-bonded electronic packages, and is described herein with regard to the double-sided cooling of an electronic package containing a single integrated circuit chip. It should be noted, however, that the method and apparatus of the present invention can be used to provide double-sided cooling to other types of single and multi-chip electronic packages without departing from the scope of the invention as set forth in the claims.

In a first aspect, the present invention provides a method for providing a double-sided cooled electronic package, comprising: positioning a plurality of heatslug members over a corresponding plurality of electronic packages formed on a leadframe strip, wherein each of the heatslug members includes a heatslug and a plurality of legs for supporting the heatslug over a respective one of the electronic packages; introducing a molding compound between each heatslug member and its respective electronic package; curing the molding compound; and cutting the heatslug members and separating the electronic packages from the leadframe strip, such that each electronic package includes a heatslug for cooling a first side of the electronic package.

In a second aspect, the present invention provides a method for providing a double-sided cooled electronic package, comprising: positioning a heatslug member over an electronic package, wherein the heatslug member includes a heatslug and a plurality of legs for supporting the heatslug over the electronic package; introducing a molding compound between the heatslug member and the electronic package; curing the molding compound; and cutting the legs of the heatslug member away such that only the heatslug remains, wherein the heatslug cools a first side of the electronic package.

In a third aspect, the present invention provides a double-sided cooled electronic package, comprising: at least one integrated circuit chip mounted on a leadframe that acts as a heatsink for cooling a first side of the electronic package; a thermally conductive heatslug; and an electrically insulating and thermally conductive molding compound for supporting the heatslug above the at least one integrated circuit chip, wherein the heatslug cools a second side of the electronic package.

These and other features of this invention will be more readily understood from the following detailed description of the various aspects of the invention taken in conjunction with the accompanying drawings in which:

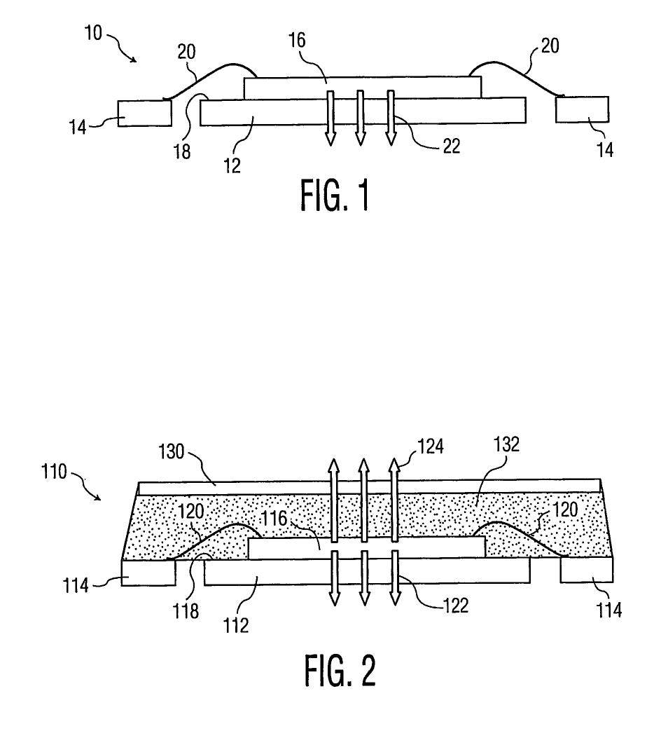

FIG. 1 illustrates a conventional leadframe package prior to overmolding;

FIG. 2 illustrates a double-sided cooled leadframe package with heatslug in accordance with the present invention;

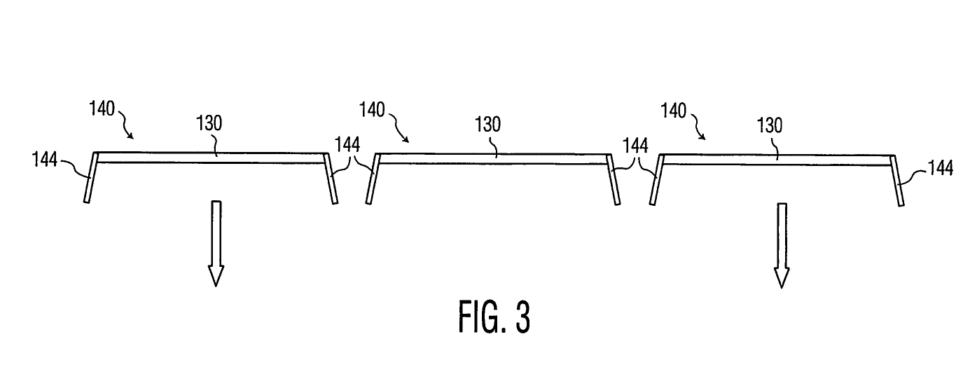

FIG. 3 illustrates a plurality of thermally conductive heatslug members in accordance with the present invention, prior to attachment to a leadframe strip;

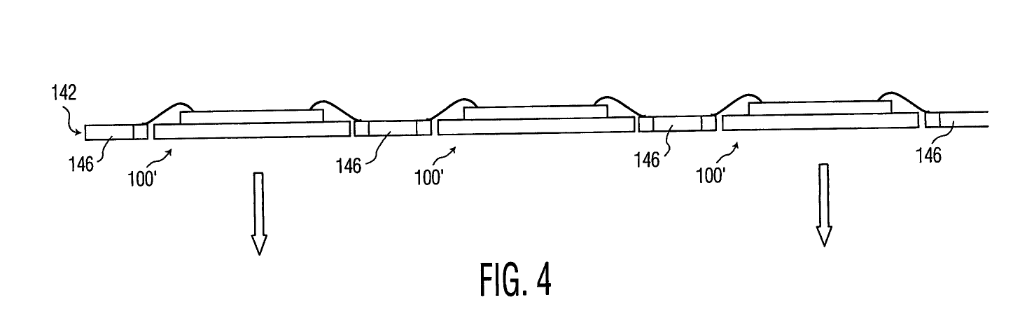

FIG. 4 illustrates a leadframe strip comprising a plurality of incomplete leadframe packages (after chip attachment and wire bonding), prior to attachment of the heatslug members shown in FIG. 3;

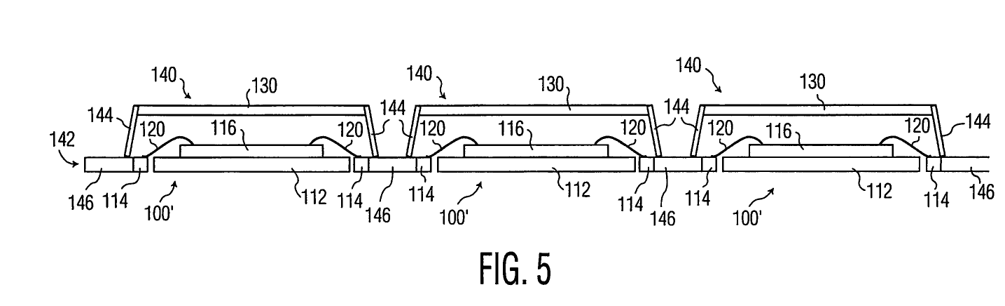

FIG. 5 illustrates the placement of the plurality of heatslug members of FIG. 3 over the incomplete leadframe packages of FIG. 4;

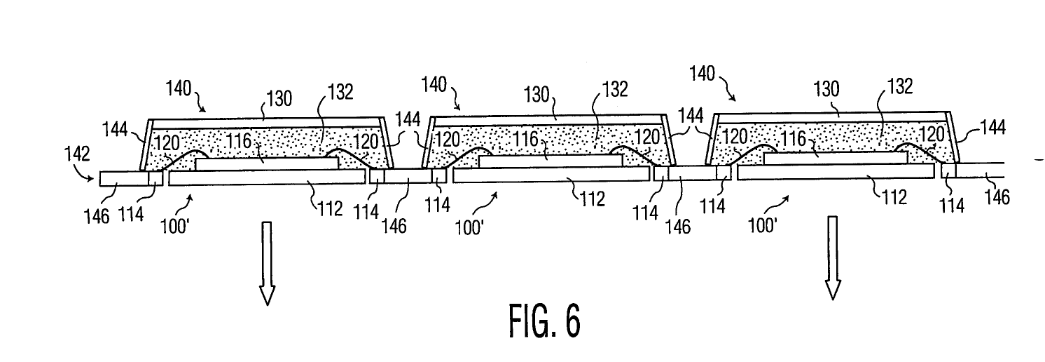

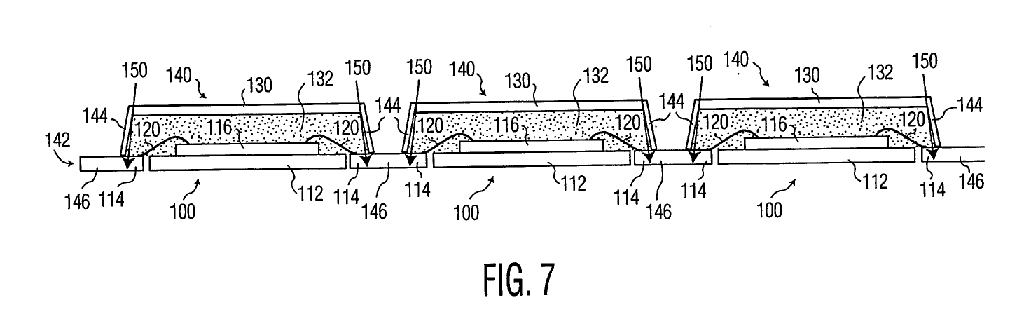

FIG. 6 illustrates the introduction of a molding compound between the heatslugs and incomplete leadframe packages; and

FIG. 7 illustrates a cutting operation for separating the completed leadframe packages from the leadframe strip.

It should be noted that the drawings are merely schematic representations, not intended to portray specific parameters of the invention. The drawings are intended to depict only typical aspects of the invention, and therefore should not be considered as limiting the scope of the invention.

A conventional leadframe package 10 is illustrated in FIG. 1. As shown, the leadframe package 10 comprises a thermally conductive leadframe/heatsink 12 and edge traces 14. An integrated circuit chip 16, such as a power MOSFET, is mounted to an upper surface 18 of the thermally conductive leadframe/heatsink 12. Wires 20 connect the integrated circuit chip 16 to the edge traces 14. Other components of the leadframe package 10 not necessary for the understanding of the present invention have not been shown for clarity. Heat generated by the integrated circuit chip 16 is dissipated from the bottom of the leadframe package 10 through the thermally conductive leadframe/heatsink 12 as generally indicated by directional arrows 22.

A leadframe package 100 produced in accordance with the present invention is illustrated in FIG. 2. Similar to the leadframe package 10 illustrated in FIG. 1, the leadframe package 100 of the present invention comprises a thermally conductive leadframe/heatsink 112 and edge traces 114. An integrated circuit chip 116, such as a power MOSFET, is mounted to an upper surface 118 of the thermally conductive leadframe/heatsink 112. Wires 120 connect the integrated circuit chip 116 to the edge traces 114. Again, other components of the leadframe package 100 not necessary for the understanding of the present invention have not been shown for clarity. Unlike the leadframe package 10 illustrated in FIG. 1, however, the leadframe package 100 of the present invention further comprises a thermally conductive heatslug 130 mounted above, and insulated from, the thermally conductive leadframe/heatsink 112, edge traces 114, integrated circuit chip 116, and wires 120, by a layer of an electrically-insulating, thermally conductive, molding compound 132. The thermally conductive heatslug 130 may be formed of a metal such as copper or aluminum, or other suitable thermally conductive material. The molding compound 132 is an epoxy-based or polymer-based molding compound of a type known in the art. Other materials having suitable thermal and electrical properties may also be used for the molding compound 132 in the practice of the present invention.

Heat generated by the integrated circuit chip 116 is dissipated from the bottom of the leadframe package 100 through the thermally conductive leadframe/heatsink 112 as generally indicated by directional arrows 122, and from the top of the leadframe package 100 through the thermally conductive heatslug 130 as generally indicated by directional arrows 124. The leadframe package 100, therefore, is now provided with double-sided cooling.

A method for producing a plurality of double-sided cooled leadframe packages 100 in accordance with the present invention is illustrated in FIGS. 3-7.

FIG. 3 illustrates a plurality of thermally conductive heatslug members 140 prior to attachment to a leadframe strip 142 (FIG. 4) that includes a plurality of incomplete leadframe packages 100′. Each heatslug member 140 includes a thermally conductive heatslug 130 and a pair of outwardly angled legs 144. Each heatslug member 140 may be formed of copper, aluminum, or other suitable thermally conductive material. As previously described, each of the plurality of leadframe packages 100′ shown in FIG. 4 generally includes at least a leadframe/heatsink 112, edge traces 114, an integrated circuit chip 116 mounted to an upper surface 118 (see FIG. 1) of the thermally conductive leadframe/heatsink 112, and wires 120 connecting the integrated circuit chip 116 to the edge traces 114. The leadframe packages 100′ are joined together on the leadframe strip 142 by removable sections 146 at adjacent edge traces 114.

As shown in FIG. 5, each heatslug member 140 is positioned on a respective leadframe package 100′, with the heatslug 130 located over the leadframe package 100′ and the outwardly angled legs 144 contacting and supported by the removable sections 146 of the leadframe strip 142 on either side of the leadframe package 100′. Although the legs 144 of each heatslug member 140 may be secured to the surface of the removable sections 146 of the leadframe strip 142 (e.g., using an adhesive, or applying force on top of the heatslug 130), it has been found that the weight of the heatslug member 140 itself is generally sufficient to maintain the heatslug member 140 in position over the leadframe package 100′ during subsequent processing steps.

The legs 144 of each heatslug member 140 do not contact the edge traces 114 of the leadframe package 100′, and position the heatslug 130 above the leadframe/heatsink 112, integrated circuit chip 116, and wires 120. In general, the legs 144 of each heatslug member 140 are configured to place the heatslug 130 of the heatslug member 140 high enough above the leadframe package 100′ such that the heatslug 130 does not contact any portion of the leadframe package 100′, thus electrically insulating the heatslug 130 from the leadframe package 100′.

After the plurality of heatslug members 140 are properly positioned over the plurality of leadframe packages 100′ of the leadframe strip 142, an electrically-insulating, thermally conductive molding compound 132 is introduced between each heatslug member 140 and its respective leadframe package 100′ as shown in FIG. 6. The overmolding may be performed, for example, by positioning a fixture(s) (not shown) over each/all of the heatslug members 140, introducing the molding compound 132 in a fluid state into the fixture(s) to fill the space between each heatslug member 140 and its respective leadframe package 100′, and allowing the molding compound 132 to cure. The molding compound 132 may comprise, for example, an epoxy-or polymer-based material heated to a temperature of approximately 175° C.

As shown in FIG. 7, after the molding compound 132 has sufficiently cured, a cutting step 150 is performed to remove the outwardly angled legs 144 from each heatslug 140 and to separate each of the now-completed leadframe packages 100 from the leadframe strip 142. The resultant double-sided cooled leadframe package 100 is shown in FIG. 2. The cutting step 150 may comprise any type of now known or later developed cutting operation that is capable of separating the leadframe packages 100 from the leadframe strip 142 and separating the legs 144 from each heatslug member 140.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

1. A method for providing a double-sided cooled electronic package (100), comprising:
positioning a plurality of heatslug members (140) over a corresponding plurality of electronic packages (100′) formed on a leadframe strip (142), wherein each of the heatslug members includes a heatslug (130) and a plurality of legs (144) for supporting the heatslug over a respective one of the electronic packages;
introducing a molding compound (132) between each heatslug member and its respective electronic package;
curing the molding compound; and
cutting (150) the heatslug members and separating the electronic packages (100) from the leadframe strip, such that each electronic package includes a heatslug for cooling a first side of the electronic package.

2. The method of claim 1, wherein the plurality of heatslug members (140) are thermally conductive.

3. The method of claim 1, wherein the plurality of heatslug members (140) are formed from a material selected from the group consisting of copper and aluminum.

4. The method of claim 1, wherein the legs (144) of each heatslug member (140) support the heatslug (130) above its corresponding electronic package (100′) such that the heatslug does not contact the electronic package.

5. The method of claim 1, wherein the molding compound (132) is electrically insulating and thermally conducting.

6. The method of claim 1, wherein each of the electronic packages (100′) formed on the leadframe strip (142) includes a leadframe (112) which acts as a heatsink to cool a second side of the electronic package.

7. The method of claim 1, wherein the plurality of electronic packages (100′) on the leadframe strip (142) are separated from each other by a removable section (146), and wherein the cutting step (150) cuts away the removable sections.

8. The method of claim 7, wherein the positioning step positions the legs (144) of the plurality of heatslug members (140) on the removable sections (146).

9. A method for providing a double-sided cooled electronic package (100), comprising:
positioning a heatslug member (140) over an electronic package (100′), wherein the heatslug member includes a heatslug (130) and a plurality of legs (144) for supporting the heatslug over the electronic package;
introducing a molding compound (132) between the heatslug member and the electronic package;
curing the molding compound; and
cutting the legs of the heatslug member away such that only the heatslug remains, wherein the heatslug cools a first side of the electronic package.

10. The method of claim 9, wherein the heatslug member (140) is thermally conductive.

11. The method of claim 9, wherein the heatslug member (140) is formed from a material selected from the group consisting of copper and aluminum.

12. The method of claim 9, wherein the legs (144) of the heatslug member (140) support the heatslug (130) above the electronic package (100′) such that the heatslug does not contact the electronic package.

13. The method of claim 9, wherein the molding compound (132) is electrically insulating and thermally conducting.

14. The method of claim 9 wherein the electronic package (100) comprises a heatsink (112) for cooling a second side of the electronic package.

15. The method of claim 9 wherein the electronic package (100′) includes removable sections (146), and wherein the cutting step (150) cuts away the legs (144) of the heatslug member (140) and the removable sections.

16. The method of claim 15, wherein the positioning step positions the legs (144) of the heatslug member (140) on the removable sections (146).

17. A double-sided cooled electronic package (100), comprising:
at least one integrated circuit chip (116) mounted on a leadframe (112) that acts as a heatsink for cooling a first side of the electronic package;
a thermally conductive heatslug (130); and
an electrically insulating and thermally conductive molding compound (132) for supporting the heatslug above the at least one integrated circuit chip, wherein the heatslug cools a second side of the electronic package.

18. The electronic package of claim 17, wherein the heatslug (130) does not contact the at least one integrated circuit chip (116).
